(19) United States
(12) Patent Application Publication
(10) Pub. No.: US 2023/0359553 A1
(43) Pub. Date: Nov. 9, 2023

(54) ACCESS TO VOLATILE MEMORIES

(71) Applicant: Hewlett-Packard Development Company, L.P., Spring, TX (US)

(72) Inventors: MASON GUNYUZLU, SPRING, TX (US); JEFFREY KEVIN JEANSONNE, SPRING, TX (US); KHOA HUYNH, SPRING, TX (US); THOMAS GEORGE SWANN, SPRING, TX (US)

(73) Assignee: Hewlett-Packard Development Company, L.P., Spring, TX (US)

(21) Appl. No.: 18/042,673

(22) PCT Filed: Oct. 23, 2020
(86) PCT No.: PCT/US2020/057066

§ 371 Date: Feb. 23, 2023

(51) Int. Cl. G06F 12/02; G06F 12/0868; G06F 13/18; G06F 13/16

(52) U.S. Cl. CPC G06F 12/0246; G06F 12/0868; G06F 13/18; G06F 13/1689; G06F 2212/7201

(57) ABSTRACT

An electronic device is described that may include an integrated circuit, a volatile memory coupled to the integrated circuit, a non-volatile memory controller coupled to the integrated circuit, and a non-volatile memory coupled to the non-volatile memory controller. In some examples, the integrated circuit is to receive a first instruction at a first frequency via a first storage access physical interface and receive a second instruction at a second frequency via a second storage access physical interface, wherein the first instruction and the second instruction are volatile memory access instructions. The integrated circuit may also be to arbitrate access to the volatile memory based on the first instruction and the second instruction and, responsive to the access to the volatile memory, synchronize contents of the volatile memory with the non-volatile memory via the non-volatile memory controller to maintain data coherency between the volatile memory and the non-volatile memory.

### BACKGROUND

Computing devices may include many different storage devices. For example, computing devices may include NOR flash storage circuits, NAND flash storage circuits, random access memories, read-only memories, etc. These and other storage devices may be implemented according to multiple different technologies or architectures.

### BRIEF DESCRIPTION OF THE DRAWINGS

Various examples will be described below referring to the following figures:

FIG. 1 is an electronic device to access a volatile memory of a storage circuit based on multiple physical interfaces in accordance with various examples.

FIG. 2 is a flowchart of a method for interacting with a storage circuit based on multiple physical interfaces in accordance with various examples.

FIG. 3 is a flowchart of a method for interacting with a storage circuit based on multiple physical interfaces in accordance with various examples.

FIG. 4 is a flowchart of a method for interacting with a storage circuit based on multiple physical interfaces in accordance with various examples.

### DETAILED DESCRIPTION

Computing devices, such as notebook computers and smartphones, include multiple discrete storage devices. Some of these storage devices have a higher cost per unit of data than other of these storage devices, but other of these storage devices that have a lower cost per unit of data may have slower read and/or write times that the storage devices that have the higher cost per unit of data. For example, Serial Peripheral Interface (SPI) NOR flash storage devices often provide high levels of performance (e.g., such as speed), but their cost also often scales approximately linearly with storage capacity. For at least this reason, some computing devices include design trade-offs either in storage capacity of the SPI NOR flash or implementation of another type of storage device in place of the SPI NOR flash to reduce cost at the expense of user-experience.

This disclosure describes various examples of a storage device that emulates NOR flash in performance at a cost per unit of data that is less than NOR flash. In some examples, the storage device includes a field programmable gate array (FPGA) or application specific integrated circuit (ASIC), a random-access memory (RAM) circuit, a NAND flash circuit, and a NAND flash controller. In at least some examples, the NAND flash controller is a digital circuit that interfaces and provides communication between the FPGA and the NAND flash circuit. The FPGA or ASIC implements multiple varied storage access physical interfaces for reading data from and writing data to the storage device. The FPGA or ASIC also implements a RAM controller for use in circumstances in which reduced latency may be beneficial, such as operations of the RAM in emulating the NOR flash. Non-volatile data is stored in the NAND flash circuit, controlled by the NAND flash controller. The NAND flash controller manages the NAND flash circuit to facilitate data resiliency and NAND flash circuit longevity.

To maintain a lower cost per unit of data than NOR flash implementations for a given memory size, such as about 128 megabytes or larger, the storage device may include a single RAM circuit rather than a RAM circuit per storage access physical interface. To facilitate the use of the single RAM circuit for multiple storage access physical interfaces, the FPGA or ASIC may operate as a data transfer arbiter. In some examples, the FPGA or ASIC receives and processes incoming commands from the storage access physical interfaces to determine and send corresponding commands to the RAM. The FPGA or ASIC also maps addresses from the storage access physical interfaces to regions within the RAM, captures data from the storage access physical interfaces, and updates the RAM based on the captured data. The FPGA or ASIC further writes data from the RAM to queues for output via the storage access physical interfaces and updates the NAND flash circuit based on the contents of the RAM to maintain coherency between the RAM and the NAND flash circuit.

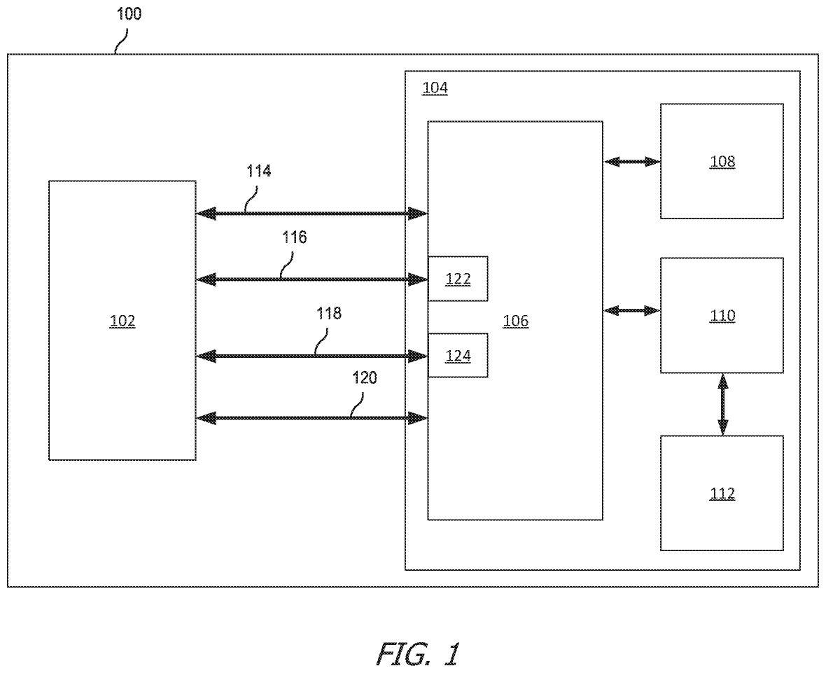

FIG. 1 is a block diagram depicting an example electronic device 100. In some examples, the electronic device 100 is an electronic device to access a volatile memory of a storage circuit based on multiple physical interfaces in accordance with various examples. In at least some examples, the electronic device 100 includes a chipset 102 and a storage circuit 104. The chipset 102, in at least some examples, enables a central processing unit (not shown) or other processor to interact with peripherals, such as the storage circuit 104. At least some implementations of the storage circuit 104 include an integrated circuit 106, a volatile memory 108, a non-volatile memory controller 110, and a non-volatile memory 112. The integrated circuit 106, in various examples, may be a FPGA or an ASIC. In at least some examples, it may increase a speed of operation of the storage circuit 104 to implement the integrated circuit 106 as a device that processes data and/or requests without needing software (such as implementing the integrated circuit 106 as a component other than a processor). For example, the integrated circuit 106 may process data without requiring code executing at run-time to instruct the integrated circuit 106 what instruction, programs, procedures, routines, etc. to execute to process the data. In this way, the integrated circuit 106 may be a hardware device (e.g., a logic device or digital logic structure), rather than a processor that executes software, facilitating faster performance of the integrated circuit 106 to process the data when compared to a processor executing software to process the data.

In some examples, implementing the integrated circuit 106 as an FPGA facilitates programmability of a hardware architecture of the integrated circuit 106, for example, to accommodate storage access physical interfaces, or more simply, physical interfaces, of varying types from the chipset 102 and/or other chipsets not shown. In at least some examples, the non-volatile memory controller 110 is a digital circuit that interfaces and provides communication between the non-volatile memory 112 and the integrated circuit 106. In at least some examples, the non-volatile memory 112 is a non-transitory computer-readable medium, where the term “non-transitory” does not encompass transitory propagating signals.

A storage access physical interface, or physical interface, is a communication protocol by which communication flows between the chipset 102 and the storage circuit 104. Some examples of such storage access physical interfaces, or physical interfaces, include serial peripheral interface (SPI), Inter-Integrated Circuit (I2C), peripheral component interconnect express (PCIe), and serial AT attachment (SATA). As shown in the electronic device 100, the integrated circuit 106 implements physical interfaces 114, 116, 118, and 120. The physical interfaces 114 and 120 facilitate communication according to protocols that include handshaking between the chipset 102 and the storage circuit 104 and the physical interfaces 116 and 118 facilitate communication according to protocols that do not include handshaking between the chipset 102 and the storage circuit 104. Collectively, the physical interfaces 114, 116, 118, and 120 may be referred to herein as physical interfaces implemented by the integrated circuit 106.

The volatile memory 108 and the non-volatile memory controller 110 are coupled to the integrated circuit 106. The non-volatile memory 112 is coupled to the non-volatile memory controller 110. In various implementations the volatile memory 108 is a RAM component, such as dynamic RAM (DRAM) or static RAM (SRAM), and the non-volatile memory 112 is a NAND flash component or other high-density storage, such as a spinning platter hard disk drive. The non-volatile memory controller 110 may take various forms based on a type of device implemented as the non-volatile memory 112. For example, the non-volatile memory controller 110 may be a NAND flash controller when the non-volatile memory controller 110 is a NAND flash component, may be a hard disk drive controller when the non-volatile memory controller 110 is a spinning platter hard disk drive, etc.

In at least some examples, the storage circuit 104 emulates or virtualizes a plurality of discrete, or separate, storage devices. In at least some examples in which the integrated circuit 106 includes X physical interfaces (e.g., communicates with the chipset 102 according to X different communication protocols), the storage circuit 104 presents itself to the chipset 102 as X discrete, or separate, storage devices. For example, some implementations of the storage circuit 104 emulate a plurality of NOR flash storage devices, with each physical interface implemented by the integrated circuit 106 appearing to the chipset 102 as a separate, discrete, NOR flash storage device.

When the storage circuit 104 exits a reset state, or powers on, the non-volatile memory controller 110 loads machine-readable instructions for its operation from the non-volatile memory 112. In some examples, the non-volatile memory controller 110 then loads machine-readable instructions for operation of the integrated circuit 106 from the non-volatile memory 112 and the integrated circuit 106 loads the machine-readable instructions for its operation from the non-volatile memory controller 110. Subsequently, the integrated circuit 106 requests the non-volatile memory controller 110 provide data from the non-volatile memory 112 to the integrated circuit 106. In some examples, such as when the storage circuit 104 emulates multiple NOR flash storage devices, the data requested by the integrated circuit 106 is the emulated NOR flash contents of the non-volatile memory 112. After being received by the integrated circuit 106, the data is stored by the integrated circuit 106 in the volatile memory 108. In at least some examples, such a process of caching the data out from the non-volatile memory 112 to the volatile memory 108 facilitates faster access by the chipset 102 to the data via the volatile memory 108 than via the non-volatile memory 112.

As discussed above, each physical interface implemented by the integrated circuit 106 appears to the chipset 102 as a separate, discrete, storage device. Because of this, the chipset 102 may provide requests to the storage circuit 104 to write data to, or read data from, multiple of these discrete storage devices simultaneously, or before processing of, or for, a previously received request is completed. To accommodate such possibilities, the integrated circuit 106 arbitrates data read and write requests received from the chipset 102 via the physical interfaces implemented by the integrated circuit 106. For example, for physical interfaces such as PCIe, SATA, or other communication protocols that include handshaking to control data flow, the integrated circuit 106 may request the chipset 102 wait to read or write data based on other processes occurring in the storage circuit 104. However, physical interfaces such as SPI or I2C may not be able to perform handshaking (e.g., such as via design choices according to those communication protocols and standards) and instead expect data read or write operations to be available substantially on-demand.

In at least some examples, the integrated circuit 106 includes caches or buffers, such as First-In, First-Out (FIFO) caches 122, 124. The caches 122 and 124 may store data associated with physical interfaces implemented by the integrated circuit 106 that do not include handshaking or other protocols that enable the integrated circuit 106 to request the chipset 102 to wait to write data to, or read data from, the storage circuit 104. For example, the cache 122 may store data associated with the physical interface 114 and the cache 124 may store data associated with the physical interface 116. Although not shown in FIG. 1, some implementations of the integrated circuit 106 include multiple caches for each physical interface, such as a data read cache and a data write cache. For the sake of discussion, the physical interface 116 and the cache 122 are discussed herein. However, similar functionality may be applicable to the physical interface 118 and the cache 124, as well as other physical interfaces and caches of the integrated circuit 106.

When the integrated circuit 106 receives data from the chipset 102 via the physical interface 116, the data is cached in the cache 122. Responsive to the cache 122 becoming full or reaching a programmed or otherwise specified amount of cached data, the integrated circuit 106 executes an instruction or request associated with the data in the cache 122. In at least some examples, executing the instruction includes writing data from the cache 122 to the volatile memory 108. For example, the cache 122 may be have a capacity sufficient to store a particular amount of data prior to overflowing. The integrated circuit 106 may determine when an amount of data cached in the cache 122 has reached a threshold amount and may schedule executes of the instruction or request associated with the data in the cache 122 to reduce an opportunity for the cache 122 to overflow, such as based on a speed, bandwidth, dataflow, and/or other characteristics associated with the physical interface 116 and/or a speed, bandwidth, and/or other characteristics associated with the volatile memory 108.

Similarly, when the integrated circuit 106 receives data read requests from the chipset 102 via the physical interface 116, the integrated circuit 106 may cache data rows from the volatile memory 108 to a data read cache (not shown) of the integrated circuit 106. In this way, the integrated circuit 106 may service data read requests received substantially simultaneously via the physical interface 116 and the physical interface 118, utilizing data cached from the volatile memory 108 to service one of the data read requests while data for the second read request is obtained from the volatile memory 108.

Additional design complexity can result from the storage circuit 104 emulating multiple discrete devices. For example, the chipset 102, when interacting with the storage circuit 104 via the physical interface 116, may expect a memory address space of [A:B]. Similarly, the chipset 102, when interacting with the storage circuit 104 via the physical interface 118, may also expect a memory address space of [A:B]. This may result from the chipset 102 viewing each physical interface implemented by the integrated circuit 106 as being a separate physical device. Because the storage circuit 104 emulates multiple devices, in at least some examples the integrated circuit 106 translates and maps memory address spaces received from the chipset 102 to a memory address space of the volatile memory 108. For example, the volatile memory 108 may have a memory address space of [A:Z]. If the integrated circuit 106 services each memory write request received from the chipset 102 with a memory address space included in the request (e.g., [A:B]), data written to the volatile memory 108 according to a first-handled of the data write requests may be at least partially overwritten by a second-handled of the data write requests when each data write request references the same memory address space.

Therefore, in at least some examples, the integrated circuit 106 translates and maps memory address spaces received via the physical interfaces implemented by the integrated circuit 106 to reduce a likelihood that a particular physical interface of the physical interfaces from overwriting data associated with a different physical interface of the physical interfaces, such as resulting from overlapping memory addresses or overlapping memory address spaces. For example, when the chipset 102 provides instructions for memory address space [A:B] on both physical interfaces 116 and 118, the integrated circuit 106 may map instructions for memory address space [A:B] received via the physical interface 116 to memory address space [A:B] of the volatile memory 108. The integrated circuit 106 may also map instructions for memory address space [A:B] received via the physical interface 116 to memory address space [B:C] (or any other suitable memory address space) of the volatile memory 108, thereby reducing a likelihood of conflicts between memory read or write instructions received via the physical interfaces 116 and 118. Although not illustrated in FIG. 1, in at least some examples the storage circuit 104 may include multiple volatile memories. In such examples, the integrated circuit 106 may maintain knowledge both of mappings between memory address spaces of the physical interfaces implemented by the integrated circuit 106 and which data regions are stored in which of the volatile memories.

Further, in at least some examples, some of the physical interfaces implemented by the integrated circuit 106 may operate at difference clock speeds. For example, instructions received via a first of the physical interfaces implemented by the integrated circuit 106 may be received at a first clock frequency and instructions received via a second of the physical interfaces implemented by the integrated circuit 106 may be received at a second clock frequency. The integrated circuit 106 may determine latency for the first and second physical interfaces implemented by the integrated circuit 106 and, based on those calculated latencies, prioritize access to the volatile memory 108 for one of the first or second physical interfaces implemented by the integrated circuit 106 over the other.

For example, assume that a first physical interfaces implemented by the integrated circuit 106 is a first SPI interface operating at a frequency of 20 megahertz (SPI1) and a second physical interfaces implemented by the integrated circuit 106 is a second SPI interface operating at a frequency of 60 megahertz (SPI2). The integrated circuit 106 may be compatible with both the 20 megahertz of SPI1 and 60 megahertz of SPI2 and may calculate a rate at which data will be received via SPI1 and SPI2. For example, the integrated circuit 106 may determine that one byte of data may be received every 33.3 nanoseconds via SPI1 and every 100 nanoseconds via SPI2. Based on this timing, the integrated circuit 106 may determine that it can service three bytes of data received via SPI1 for each one byte of data received via SPI2 and serviced. Using these determined timings, the integrated circuit 106 may, in some examples, reduce a likelihood of an overflow of a cache that is caching data received via SPI1 and/or SPI2. The frequency at which data is received via SPI1 and/oi SPI2 may change during operation of the electronic device 100 and the integrated circuit 106 may recalculate timings related to data received via SPI1 and/or SPI2 in response to the frequency change(s).

When a data bus existing between the integrated circuit 106 and the volatile memory 108 is idle, such as following the completion of data read or write requests received at the integrated circuit 106 via at least one of the physical interfaces implemented by the integrated circuit 106, data changes of the volatile memory 108 may be flushed to the non-volatile memory 112. For example, the integrated circuit 106 may read the contents of the volatile memory 108 and write the read contents of the volatile memory 108 to the non-volatile memory controller 110, which in turn writes the read contents of the volatile memory 108 to the non-volatile memory 112. This maintains coherency between the volatile memory 108 and the non-volatile memory 112 and provides data resiliency and/or persistence for the data stored by the storage circuit 104, such as when power may be lost to the storage circuit 104 and thus data stored in or by the volatile memory 108 is lost.

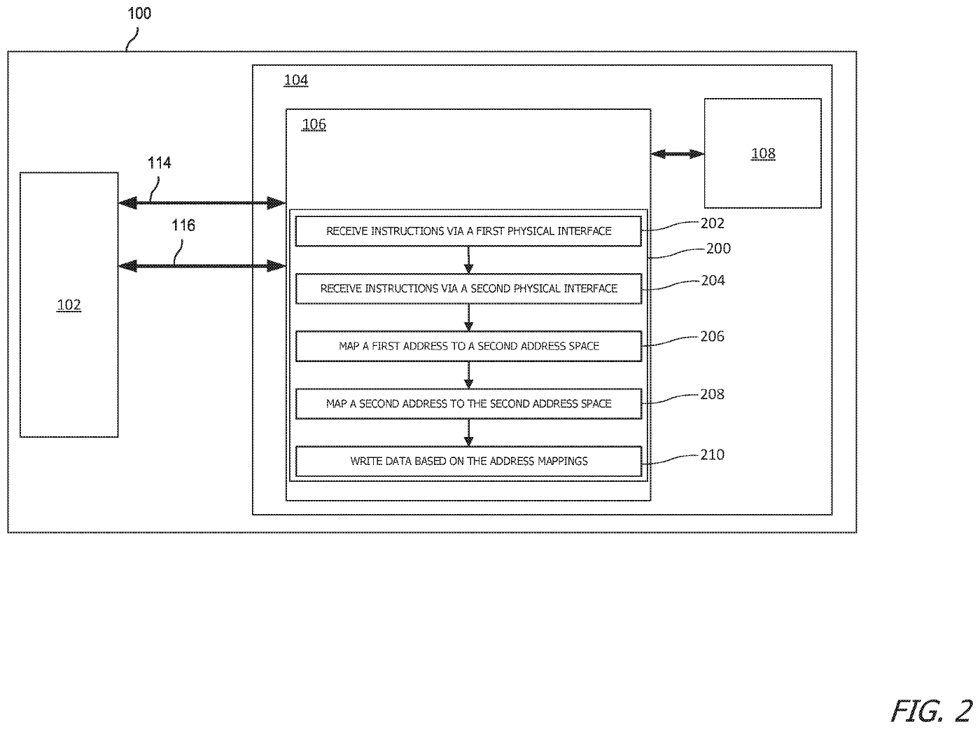

FIG. 2 is a flowchart depicting a method 200. In some examples, the method 200 is a method for interacting with a storage circuit based on multiple physical interfaces. In at least some examples, the method 200 is implemented by the integrated circuit 106 of the electronic device 100 of FIG. 1. Accordingly, reference is made in FIG. 2 to components of FIG. 1, but those components of FIG. 1 are not separately described herein with respect to FIG. 2. The method 200 is implemented to, for example, receive and write data to a storage circuit, such as the storage circuit 104, that emulates multiple discrete storage devices each corresponding to separate or different physical interfaces. In some examples, the integrated circuit 106 implements operations of the method 300 based on a hardware architecture of the integrated circuit 106, which may be programmable (such as when the integrated circuit 106 is a FPGA) or non-programmable (such as when the integrated circuit 106 is an ASIC).

At operation 202, the integrated circuit receives instructions from a chipset via a first physical interface for writing first data to the storage circuit. In at least some examples, the first physical interface corresponds to a first emulated storage device, emulated by the storage circuit. In at least some examples, the instructions for writing the first data to the storage circuit are for writing the instructions to a first address space, or first memory address space, of the storage circuit.

At operation 204, the integrated circuit receives instructions from a chipset via a second physical interface for writing second data to the storage circuit. In at least some examples, the second physical interface corresponds to a second emulated storage device, emulated by the storage circuit. In at least some examples, the instructions for writing the second data to the storage circuit are for writing the instructions to the first address space, or first memory address space, of the storage circuit.

At operation 206, the integrated circuit maps a first address in a first address space to a second address space of the volatile memory. The first address is, in some examples, received via the first physical interface in the instructions for writing the first data to the storage circuit. The second address space, in at least some examples, includes the second address space. For example, when the first address space begins at address A and ends at address B, the second address space may begin at address A and end at address C (or any other suitable address).

At operation 208, the integrated circuit maps a second address in the first address space to the second address space of the volatile memory. The second address is, in some examples, received via the second physical interface in the instructions for writing the second data to the storage circuit.

At operation 210, the integrated circuit writes the first data and the second data to a volatile memory based on the address mappings of the first address and the second address. In at least some examples, the volatile memory is a RAM of the storage circuit that emulates multiple discrete storage devices, such as multiple NOR flash storage devices.

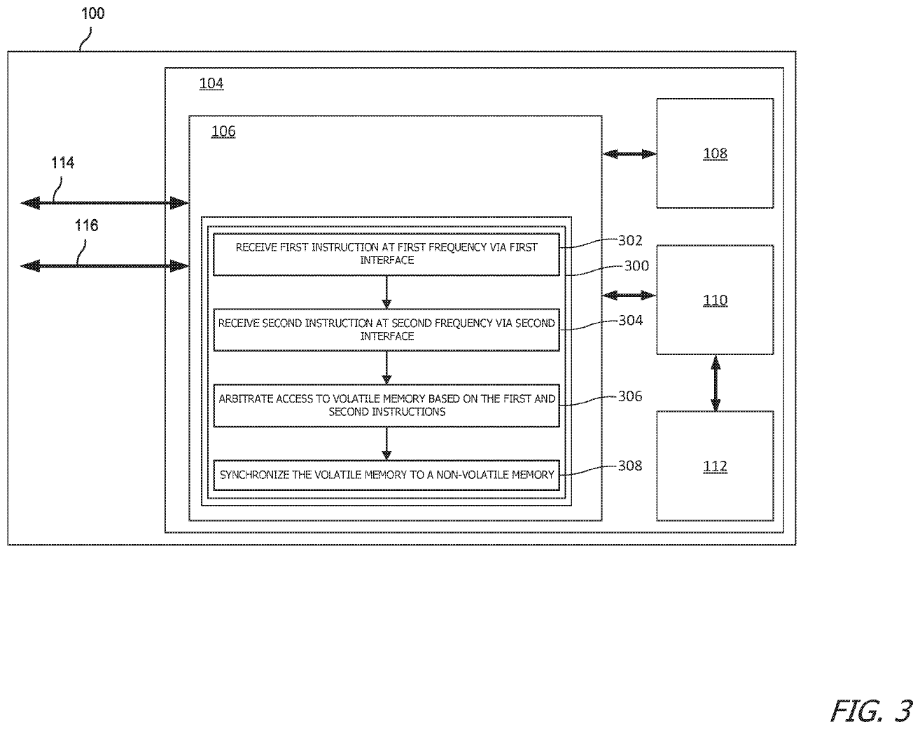

FIG. 3 is a flowchart depicting a method 300. In some examples, the method 300 is a method for interacting with a storage circuit based on multiple physical interfaces. In at least some examples, the method 300 is implemented by the integrated circuit 106 of the electronic device 100 of FIG. 1. Accordingly, reference is made in FIG. 3 to components of FIG. 1, but those components of FIG. 1 are not separately described herein with respect to FIG. 3. The method 300 is implemented to, for example, receive and write data to a storage circuit that emulates multiple discrete storage devices each corresponding to separate or different physical interfaces. In some examples, the integrated circuit 106 implements operations of the method 300 based on a hardware architecture of the integrated circuit 106, which may be programmable (such as when the integrated circuit 106 is a FPGA) or non-programmable (such as when the integrated circuit 106 is an ASIC).

At operation 302, the integrated circuit receives a first instruction at a first frequency via a first storage access physical interface. The first instruction is, in some examples, an instruction to write data to a memory or an instruction to read data from the memory. In at least some examples, the memory referenced by the first instruction is a discrete memory (e.g., a memory unique to the first storage access physical interface). The integrated circuit, in at least some examples, maps the first instruction to operations associated with a volatile memory.

At operation 304, the integrated circuit receives a second instruction at a second frequency via a second storage access physical interface, wherein the first instruction and the second instruction are volatile memory access instructions. The second instruction is, in some examples, an instruction to write data to a second memory or an instruction to read data from the second memory. In at least some examples, the second memory referenced by the second instruction is a discrete memory (e.g., a memory unique to the second storage access physical interface). The integrated circuit, in at least some examples, maps the second instruction to operations associated with the volatile memory.

At operation 306, the integrated circuit arbitrates access to the volatile memory based on the first instruction and the second instruction. In some examples, aspects of the first instruction and the second instruction conflict. For example, one of the first or second instructions may request data operations while data operations of the other instruction are being serviced. Similarly, the first instruction and the second instruction may reference a same memory address space, or same memory address, and therefore conflict or overlap in the volatile memory. Yet further, in some examples the first instruction and the second instruction may be received at different clock frequencies and the integrated circuit may prioritize access to the volatile memory based on latencies determined according to the different clock frequencies.

At least some implementations of the integrated circuit compensate for these conflicts between the first and second instructions by arbitrating access to the volatile memory. For example, by prioritizing access to the volatile memory, caching data associated to one of the first or second instructions, and/or remapping an address space of one of the first or second instructions to an address space of the volatile memory, the integrated circuit accesses the volatile memory based on the first and second instructions.

At operation 308, responsive to the access to the volatile memory, the integrated circuit synchronizes contents of the volatile memory with the non-volatile memory via the non-volatile memory controller to maintain data coherency between the volatile memory and the non-volatile memory. In at least some examples, the integrated circuit synchronizes the contents of the volatile memory with the non-volatile memory by flushing the volatile memory to the non-volatile memory. As used herein, flushing the volatile memory to the non-volatile memory includes copying contents of the volatile memory to the non-volatile memory, which in some examples may include an address translation or remapping between an address space of the volatile memory and an address space of the non-volatile memory.

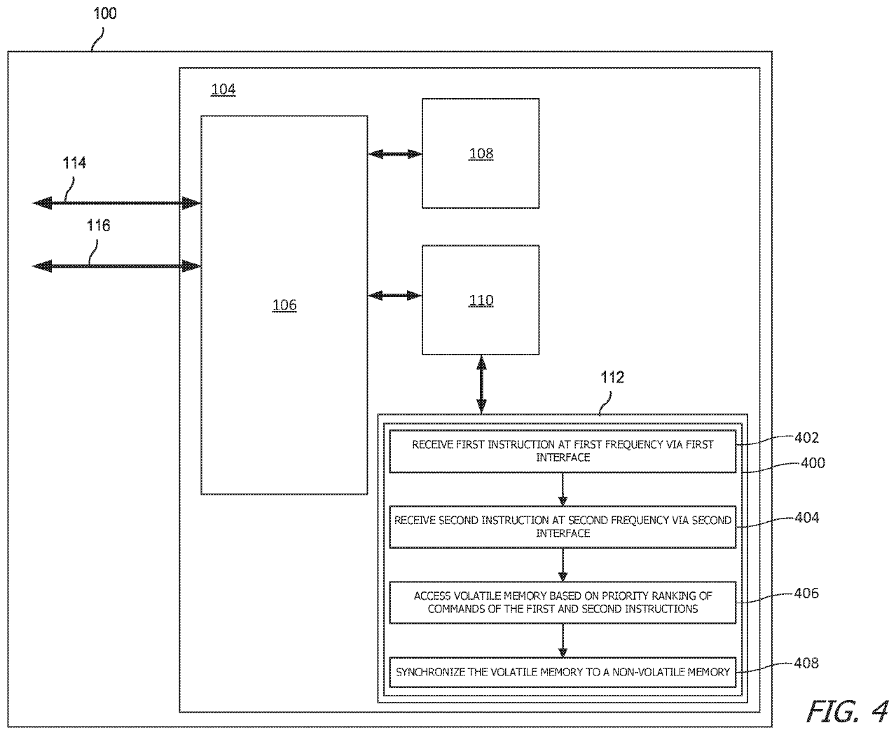

FIG. 4 is a flowchart depicting a method 400. In some examples, the method 400 is a method for interacting with a storage circuit based on multiple physical interfaces. In at least some examples, the method 400 is implemented by the integrated circuit 106 of the electronic device 100 of FIG. 1. Accordingly, reference is made in FIG. 4 to components of FIG. 1, but those components of FIG. 1 are not separately described herein with respect to FIG. 4. The method 400 is implemented to, for example, receive and write data to a storage circuit that emulates multiple discrete storage devices each corresponding to separate or different physical interfaces. In at least some examples, the method 400 is stored as executable instructions, or executable code, such as in the non-volatile memory 112 of the storage circuit 104, that are transferred to the integrated circuit 106 for execution. In other examples, the method 400 is stored as executable code or instructions in the non-volatile memory 112 that when provided to the integrated circuit 106, cause the integrated circuit 106 to have a particular hardware architecture.

At operation 402, the integrated circuit receives, via a first physical interface, a first instruction at a first frequency for accessing a volatile memory. The first instruction is, in some examples, an instruction to write data to a memory or an instruction to read data from the memory. In at least some examples, the memory referenced by the first instruction is a discrete memory (e.g., a memory unique to the first storage access physical interface). The integrated circuit, in at least some examples, maps the first instruction to operations associated with a volatile memory.

At operation 404, the integrated circuit receives, via a second physical interface, a second instruction at a second frequency for accessing the volatile memory. The second instruction is, in some examples, an instruction to write data to a second memory or an instruction to read data from the second memory. In at least some examples, the second memory referenced by the second instruction is a discrete memory (e.g., a memory unique to the second storage access physical interface). The integrated circuit, in at least some examples, maps the second instruction to operations associated with the volatile memory.

At operation 406, the integrated circuit accesses the volatile memory based on the first instruction and the second instruction by arbitrating the first instruction and the second instruction to create a priority ranking of commands of the first instruction and the second instruction. For example, the integrate circuit may create the priority ranking based on latencies associated with the first instruction or the second instruction, the first and second clock frequencies, a portion of the volatile memory to be accessed according to the first instruction or the second instruction, or any other suitable consideration.

At operation 408, responsive to accessing the volatile memory, the integrated circuit synchronizes contents of the volatile memory with a non-volatile memory via a non-volatile memory controller to maintain data coherency between the volatile memory and the non-volatile memory. In at least some examples, the integrated circuit synchronizes the contents of the volatile memory with the non-volatile memory by flushing the volatile memory to the non-volatile memory. Maintaining coherency between the volatile memory and the non-volatile memory, in at least some examples, increases resiliency of the data stored by the volatile memory and the non-volatile memory.

The above discussion is meant to be illustrative of the principles and various examples of the present disclosure. Numerous variations and modifications will become apparent to those skilled in the art once the above disclosure is fully appreciated. It is intended that the following claims be interpreted to embrace all such variations and modifications.

What is claimed is:

1. An electronic device, comprising:
a chipset; and
a storage circuit coupled to the chipset and comprising a volatile memory and an integrated circuit, the integrated circuit to:
receive instructions from the chipset via a first physical interface for writing first data to the storage circuit;
receive instructions from the chipset via a second physical interface for writing second data to the storage circuit;
map a first address in a first address space to a second address space of the volatile memory, wherein the first address is received via the first physical interface, and wherein the second address space includes the first address space;
map a second address in the first address space to the second address space, wherein the second address is received via the second physical interface; and
access the volatile memory to write the first data and the second data to the volatile memory based on the address mappings of the first address and the second address.

2. The electronic device of claim 1, wherein the integrated circuit is to receive the instructions from the chipset via the first physical interface at a first clock frequency and the instructions from the chipset via the second physical interface at a second clock frequency.

3. The electronic device of claim 1, wherein the integrated circuit is to:
receive the instructions from the chipset via the first physical interface and the instructions via the second physical interface including overlapping memory addresses; and
resolve the overlapping memory addresses.

4. The electronic device of claim 1, wherein the integrated circuit caches the first data to a cache of the integrated circuit and writes the first data to the volatile memory after the cache is full.

5. The electronic device of claim 1, wherein the storage circuit emulates multiple discrete storage devices, a first of the multiple discrete storage devices uniquely corresponding to the first physical interface and a second of the multiple discrete storage devices corresponding to the second physical interface.

6. An electronic device, comprising:
an integrated circuit;
a volatile memory coupled to the integrated circuit;
a non-volatile memory controller coupled to the integrated circuit; and
a non-volatile memory coupled to the non-volatile memory controller,
wherein the integrated circuit is to:
receive a first instruction at a first frequency via a first storage access physical interface;
receive a second instruction at a second frequency via a second storage access physical interface, wherein the first instruction and the second instruction are volatile memory access instructions;
arbitrate access to the volatile memory based on the first instruction and the second instruction; and
responsive to the access to the volatile memory, synchronize contents of the volatile memory with the non-volatile memory via the non-volatile memory controller to maintain data coherency between the volatile memory and the non-volatile memory.

7. The electronic device of claim 6, wherein the volatile memory and the non-volatile memory each emulate multiple discrete storage devices, a first of the multiple discrete storage devices uniquely corresponding to the first storage access physical interface and a second of the multiple discrete storage devices corresponding to the second storage access physical interface.

8. The electronic device of claim 7, wherein arbitrating access includes resolving an overlapping conflict between a memory address associated with the first instruction and a memory address associated with the second instruction.

9. The electronic device of claim 7, wherein arbitrating access includes prioritizing one of the first instruction or the second instruction based on latencies determined according to the first frequency and the second frequency.

10. The electronic device of claim 7, wherein arbitrating access includes caching data associated with one of the first instruction or the second instruction in the integrated circuit while the integrated circuit services the other of the first instruction or the second instruction.

11. A non-transitory computer-readable medium storing executable code, which, when executed by an integrated circuit of an electronic device, causes the integrated circuit to:
receive, via a first physical interface, a first instruction at a first frequency for accessing a volatile memory;
receive, via a second physical interface, a second instruction at a second frequency for accessing the volatile memory;
access the volatile memory based on the first instruction and the second instruction by arbitrating the first instruction and the second instruction to create a priority ranking of commands of the first instruction and the second instruction; and
responsive to the access to the volatile memory, synchronize contents of the volatile memory with a non-volatile memory via a non-volatile memory controller to maintain data coherency between the volatile memory and the non-volatile memory.

12. The computer-readable medium of claim 11, wherein arbitrating the first instruction and the second instruction includes determining latencies associated with the first frequency and the second frequency and creating the priority ranking of commands of the first instruction and the second instruction according to the determined latencies.

13. The computer-readable medium of claim 12, wherein arbitrating the first instruction and the second instruction also includes resolving overlapping address spaces of the first instruction and the second instruction by remapping a memory address of the first instruction and the second instruction to a different address of the volatile memory.

14. The computer-readable medium of claim 12, wherein arbitrating the first instruction and the second instruction also includes caching data associated with the first instruction or the second instruction while the other of the first instruction or the second instruction is serviced.

15. The computer-readable medium of claim 11, wherein the volatile memory and the non-volatile memory each emulate multiple discrete storage devices, a first of the multiple discrete storage devices uniquely corresponding to the first physical interface and a second of the multiple discrete storage devices corresponding to the second physical interface.
